(19) United States
(12) Patent Application Publication
(10) Pub. No.: US 2008/0198666 A1
(43) Pub. Date: Aug. 21, 2008

(54) Semiconductor device including adjustable driver output impedances

(76) Inventor: Aaron Nygren, San Francisco, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/708,223

(22) Filed: Feb. 20, 2007

(51) Int. Cl. G11C 11/34

(52) U.S. Cl. 365/185.24

(57) ABSTRACT

A semiconductor device is disclosed. In one embodiment, the device includes a first circuit, a second circuit, and a third circuit. The first circuit is configured to drive output signals and includes an adjustable output impedance. The second circuit is configured to adjust the adjustable output impedance. The third circuit is configured to sense a first parameter and to activate the second circuit to adjust the adjustable output impedance based on changes in the first parameter exceeding a first threshold value.

### BACKGROUND

Typically, an electronic system includes a number of integrated circuit chips that communicate with one another to perform system applications. Often, the electronic system includes a controller, such as a micro-processor, and one or more memory chips, such as random access memory (RAM) chips. The controller communicates with the memory to store data and to read the stored data.

The RAM chips can be any suitable type of RAM, such as dynamic RAM (DRAM) including single data rate synchronous DRAM (SDR-SDRAM), double data rate SDRAM (DDR-SDRAM), graphics DDR-SDRAM (GDDR-SDRAM), low power SDR-SDRAM (LPSDR-SDRAM), and low power DDR-SDRAM (LPDDR-SDRAM). Also, the RAM chips can be any suitable generation of memory including fourth generation DDR-SDRAM (DDR4-SDRAM), fifth generation GDDR-SDRAM (GDDR5-SDRAM), and higher generations of memory. Usually, each new generation of memory operates at an increased clock speed and/or an increased data rate from the previous generation.

Some memories include automatic regulation of off-chip driver output impedances. The off-chip driver output impedances may be regulated to optimize system timing affected by the regulated impedances. The driver output impedances are regulated to specified impedance values independent of manufacturing process, operating temperature, and operating voltage. The automatic regulation circuits operate in the background of normal chip operation.

Often, automatic regulation circuits and off-chip drivers include adjustable driver output impedances that are adjusted via digital steps. Digital circuitry enables and disables parallel drivers to achieve the specified impedance value. The exactness of the regulated impedance value is limited by the digital resolution of the parallel driver steps. This leads to quantization error in the regulated impedance value, which changes from time to time between adjacent impedance values. Even if all parameters such as temperature and voltage are stable, the automatic regulation or calibration circuit continues to run with the final result being based on noise in the system. Toggling between adjacent impedance values makes it difficult to optimize system timing affected by the regulated driver output impedance. Also, continuously running the calibration circuit uses power continuously.

For these and other reasons there is a need for the present invention.

### SUMMARY

The present disclosure describes a semiconductor device including adjustable output impedances. One embodiment provides a semiconductor device including a first circuit, a second circuit, and a third circuit. The first circuit is configured to drive output signals and includes an adjustable output impedance. The second circuit is configured to adjust the adjustable output impedance. The third circuit is configured to sense a first parameter and to activate the second circuit to adjust the adjustable output impedance based on changes in the first parameter exceeding a first threshold value.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an electronic system according to the present invention.

FIG. 2 is a block diagram illustrating one embodiment of an electronic system including a host controller and a RAM.

FIG. 3 is a diagram illustrating one embodiment of a memory cell in the RAM.

FIG. 4 is a diagram illustrating one embodiment of a calibration circuit.

FIG. 5 is a diagram illustrating one embodiment of an input/output (10) circuit.

FIG. 6 is a flow chart diagram illustrating one embodiment of regulating the adjustable driver output impedances.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

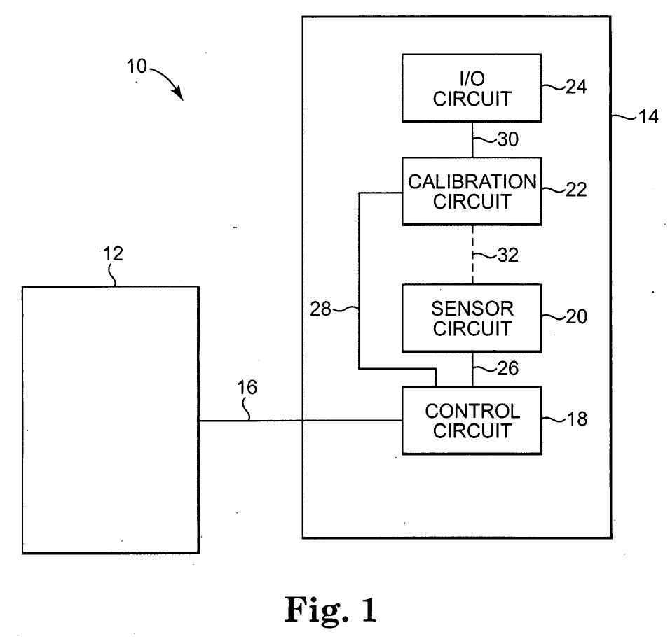

FIG. 1 is a block diagram illustrating one embodiment of an electronic system 10 according to the present invention. Electronic system 10 includes a first semiconductor device 12 and a second semiconductor device 14. First semiconductor device 12 is electrically coupled to second semiconductor device 14 via communications path 16. In one embodiment, first semiconductor device 12 is a host controller and second semiconductor device 14 is a RAM, where the controller and RAM communicate with one another via communications path 16 to perform system applications. In one embodiment, second semiconductor device 14 is any suitable type of memory such as a DRAM, an SDR-SDRAM, a DDR-SDRAM, a GDDR-SDRAM, a LPSDR-SDRAM, or a LPDDR-SDRAM and second semiconductor device 14 is any suitable generation of memory. In one embodiment, first semiconductor device 12 and second semiconductor device 14 are integrated circuits. In one embodiment, first semiconductor device 12 and second semiconductor device 14 are separate integrated circuit chips. In one embodiment, first semiconductor device 12 and second semiconductor device 14 are in the same integrated circuit chip. In other embodiments, first semiconductor device 12 and second semiconductor device 14 can be any suitable circuit types.

Second semiconductor device 14 includes a control circuit 18, a sensor circuit 20, a calibration circuit 22, and an input/output (I/O) circuit 24. Control circuit 18 is electrically coupled to sensor circuit 20 via signal path 26 and control circuit 18 is electrically coupled to calibration circuit 22 via calibrate signal path 28. In addition, control circuit 18 is electrically coupled to first semiconductor device 12 via communications path 16. Calibration circuit 22 is electrically coupled to I/O circuit 24 via signal path 30. In one embodiment, sensor circuit 20 is electrically coupled to calibration circuit 22 via sensor circuit calibrate signal path 32.

I/O circuit 24 drives output signals out of semiconductor device 14 and includes adjustable driver output impedances. In one embodiment, I/O circuit 24 includes adjustable driver output impedances that are adjusted via digital steps, where digital circuitry enables and disables parallel drivers to achieve the specified impedance value.

Sensor circuit 20 senses one or more parameters. In one embodiment, sensor circuit 20 provides sensed signals that correspond to the one or more parameters. In one embodiment, sensor circuit 20 provides sensed signals that represent a change in the one or more parameters. In one embodiment, sensor circuit 20 is a combination of analog and digital circuitry. In one embodiment, sensor circuit 20 provides digital sensed signal outputs. In one embodiment, sensor circuit 20 is similar to a temperature sensor that is used for a band gap circuit and/or a voltage generator. In one embodiment, sensor circuit 20 is similar to a voltage sensor that includes multiple comparators and a resistor ladder coupled to the comparators. In one embodiment, sensor circuit 20 senses the temperature of semiconductor device 14. In one embodiment, sensor circuit 20 senses the power supply voltage of semiconductor device 14. In one embodiment, sensor circuit 20 senses the temperature and the power supply voltage of semiconductor device 14.

If changes in the one or more parameters exceed corresponding threshold values, an active calibrate signal is provided to calibration circuit 22. Calibration circuit 22 adjusts the adjustable driver output impedances to the specified impedance value based on receiving the active calibrate signal. In one embodiment, an active calibrate signal is also provided to calibration circuit at power up initialization.

In one embodiment, changes in temperature are compared to a temperature change threshold value and if the change in temperature exceeds the temperature change threshold value an active calibrate signal is provided to the calibration circuit 22. In one embodiment, a change in power supply voltage is compared to a power supply voltage change threshold value and if the change in the power supply voltage exceeds the power supply voltage change threshold value an active calibrate signal is provided to the calibration circuit 22. In one embodiment, a change in temperature is compared to a temperature change threshold value and a change in power supply voltage is compared to a power supply voltage change threshold value and if the change in temperature exceeds the temperature change threshold value and the change in the power supply voltage exceeds the power supply voltage change threshold value an active calibrate signal is provided to the calibration circuit 22. In one embodiment, calibration circuit 22 is powered off after calibrating or adjusting the adjustable output impedances, which reduces power consumption.

In one embodiment, sensor circuit 20 senses one or more parameters and provides sensed signals from the one or more parameters to control circuit 18 via signal path 26. Control circuit 18 processes the sensed signals and if changes in the one or more parameters exceed corresponding threshold values control circuit 18 provides an active calibrate signal to calibration circuit 22 via calibrate signal path 28. Calibration circuit 22 adjusts the adjustable driver output impedances to the specified impedance value based on receiving the active calibrate signal.

In one embodiment, sensor circuit 20 senses one or more parameters and provides sensed signals from the one or more parameters to control circuit 18 via signal path 26. Control circuit 18 receives the sensed signals and provides corresponding sensed signals to first semiconductor device 12 via communications path 16. First semiconductor device 12 processes the sensed signals and if changes in the one or more parameters exceed corresponding threshold values first semiconductor device 12 provides an active calibrate signal to control circuit 18, which provides the active calibration signal to calibration circuit 22 via calibrate signal path 28. Calibration circuit 22 adjusts the adjustable driver output impedances to the specified impedance value based on receiving the active calibrate signal.

In one embodiment, sensor circuit 20 senses the one or more parameters and processes sensed signals from the one or more parameters. If changes in the one or more parameters exceed corresponding threshold values, sensor circuit 20 provides an active calibrate signal to control circuit 18 via signal path 26. Control circuit 18 provides a corresponding active calibrate signal to calibration circuit 22 via calibrate signal path 28. Calibration circuit 22 adjusts the adjustable driver output impedances to the specified impedance values based on receiving the active calibrate signal.

In one embodiment, sensor circuit 20 senses the one or more parameters and processes sensed signals from the one or more parameters. If changes in the one or more parameters exceed corresponding threshold values, sensor circuit 20 provides an active calibrate signal directly to calibration circuit 22 via sensor circuit calibrate signal path 32. Calibration circuit 22 adjusts the adjustable driver output impedances to the specified impedance values based on receiving the active calibrate signal.

In one embodiment, first semiconductor device 12 includes a sensor circuit that senses one or more parameters such as temperature and power supply voltage. If changes in the one or more parameters exceed corresponding threshold values, first semiconductor device 12 provides an active calibrate signal to control circuit 18, which provides the active calibration signal to calibration circuit 22 via calibrate signal path 28. Calibration circuit 22 adjusts the adjustable driver output impedances to the specified impedance value based on receiving the active calibrate signal.

In other embodiments, first semiconductor device 12 communicates directly with sensor circuit 20 and/or calibration circuit 22.

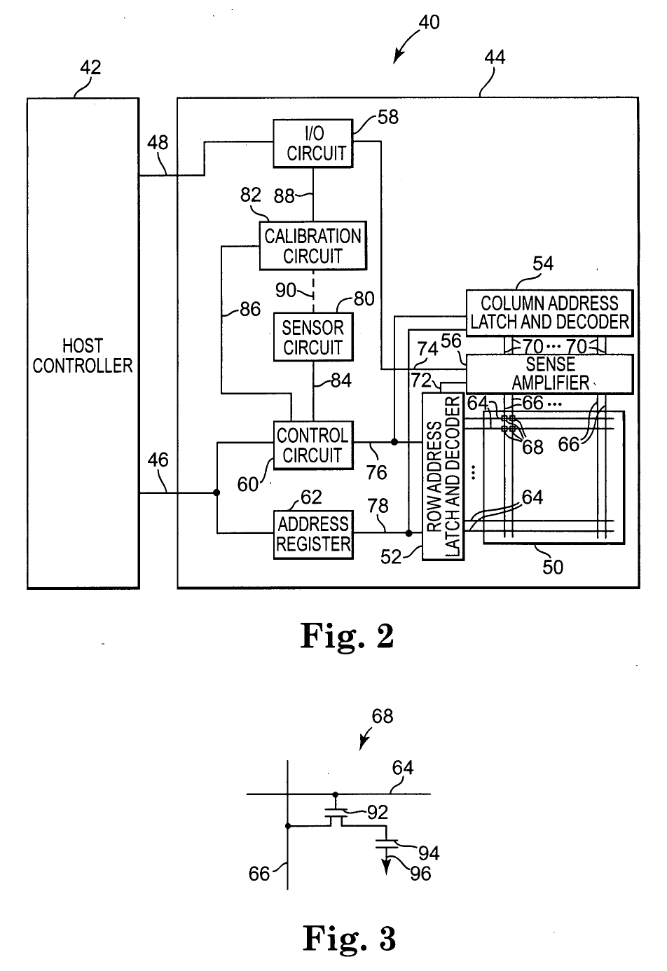

FIG. 2 is a block diagram illustrating one embodiment of an electronic system 40 according to the present invention. Electronic system 40 includes a host controller 42 and a RAM 44. Controller 42 is electrically coupled to RAM 44 via memory communications path 46 and data communications path 48. Controller 42 provides row and column addresses and control signals to RAM 44 via memory communications path 46. Controller 42 provides data signals and strobe signals to RAM 44 and receives data signals and strobe signals from RAM 44 via data communications path 48. RAM 44 can be any suitable type of RAM, such as a DRAM, an SDR-SDRAM, a DDR-SDRAM, a GDDR-SDRAM, a LPSDR-SDRAM, or a LPDDR-SDRAM.

RAM 44 includes an array of memory cells 50, a row address latch and decoder 52, a column address latch and decoder 54, a sense amplifier circuit 56, a RAM I/O circuit 58, a control circuit 60, an address register 62, a sensor circuit 80, and a calibration circuit 82. Conductive word lines 64, referred to as row select lines, extend in the x-direction across the array of memory cells 50. Conductive bit lines. 66, referred to as digit lines, extend in the y-direction across the array of memory cells 50. A memory cell 68 is located at each cross point of a word line 64 and a bit line 66.

Each word line 64 is electrically coupled to row address latch and decoder 52 and each bit line 66 is electrically coupled to one of the sense amplifiers in sense amplifier circuit 56. The sense amplifier circuit 56 is electrically coupled to column address latch and decoder 54 via conductive column select lines 70. Also, sense amplifier circuit 56 is electrically coupled to row address latch and decoder 52 via communications path 72 and to RAM I/O circuit 58 via I/O communications path 74. RAM I/O circuit 58 is electrically coupled to controller 42 via data communications path 48. Data signals and strobe signals are transferred between RAM I/O circuit 58 and controller 42 via data communications path 48.

Controller 42 is electrically coupled to RAM I/O circuit 58 via data communications path 48 and to control circuit 60 and address register 62 via memory communications path 46. Address register 62 is electrically coupled to row address latch and decoder 52 and column address latch and decoder 54 via row and column address lines 78. Control circuit 60 is electrically coupled to row address latch and decoder 52 and column address latch and decoder 54 via control communications path 76. Control circuit 60 is also electrically coupled to sensor circuit 80 via signal path 84 and to calibration circuit 82 via calibrate signal path 86. Calibration circuit 82 is electrically coupled to RAM I/O circuit 58 via I/O signal path 88. In one embodiment, sensor circuit 80 is electrically coupled to calibration circuit 82 via sensor circuit calibrate signal path 90.

Address register 62 receives row and column addresses from controller 42 via memory communications path 46. Address register 62 supplies a row address to row address latch and decoder 52 via row and column address lines 78, and control circuit 60 supplies a RAS signal to row address latch and decoder 52 via control communications path 76 to latch the supplied row address into row address latch and decoder 52. Address register 62 supplies a column address to column address latch and decoder 54 via row and column address lines 78, and control circuit 60 supplies a CAS signal to column address latch and decoder 54 via control communications path 76 to latch the supplied column address into column address latch and decoder 54.

Row address latch and decoder 52 receives row addresses and RAS signals and latches the row addresses into row address latch and decoder 52. Row address latch and decoder 52 decodes each of the row addresses to select a row of memory cells 68. In addition, row address latch and decoder 52 provides sense amplifier activation signals and equalization and precharge signals to sense amplifier circuit 56 via communications path 72.

Column address latch and decoder 54 activates column select lines 70 to connect sense amplifiers in sense amplifier circuit 56 to RAM I/O circuit 58. Column address latch and decoder 54 receives a column address and latches the column address into column address latch and decoder 54. Column address latch and decoder 54 decodes the column address to select addressed column select lines 70. In addition, column address latch and decoder 54 receives column select line activation signals from control circuit 60 via control communications path 76. The column select line activation signals indicate which of the addressed column select lines 70 are to be activated by column address latch and decoder 54. Column address latch and decoder 54 activates column select lines 70 that are addressed by the column address and selected for activation by the column select line activation signals. Activated column select lines 70 are provided to sense amplifier circuit 56 to connect sense amplifiers in sense amplifier circuit 56 to RAM I/O circuit 58.

Control circuit 60 receives addresses and control signals from controller 42 via memory communications path 46. Controller 42 provides control signals, such as read/write enable, RAS, and CAS signals, to control circuit 60. Control circuit 60 provides RAS signals to row address latch and decoder 52 and CAS signals to column address latch and decoder 54. Also, control circuit 60 provides control signals to column address latch and decoder. 54 to selectively activate column select lines 70.

Sense amplifier circuit 56 includes sense amplifiers, equalization and precharge circuits, and switches. In one embodiment, the sense amplifiers are differential input sense amplifiers and each sense amplifier receives one bit line 66 at each of two differential inputs. One of the differential inputs receives a data bit from a selected memory cell 68 and the other one of the differential inputs is used as a reference. The equalization and precharge circuits equalize the voltage on the bit lines 66 connected to the same sense amplifier prior to a read or write operation.

To read a data bit, a sense amplifier amplifies the difference between the data bit value and the reference value and provides a sensed output value to RAM I/O circuit 58 via I/O communications path 74. RAM I/O circuit 58 receives the sensed output value and outputs the sensed output value. In one embodiment, RAM I/O circuit 58 outputs the sensed output value to controller 42 via data communications path 48.

To write a data bit, controller 42 provides a data signal to RAM I/O circuit 58 via data communications path 48. RAM I/O circuit 58 receives the data signal and provides each data bit to a sense amplifier in sense amplifier circuit 56 via I/O communications path 74. RAM I/O circuit 58 overdrives the sense amplifier to drive the data bit value onto a bit line 66 that is connected to one of the memory cells 68. RAM I/O circuit 58 also overdrives the inverse of the data bit value onto the reference bit line 66. The sense amplifier writes the received data bit value into the selected memory cell 68.

RAM I/O circuit 58 provides data and strobe signals to controller 42 via data communications path 48. RAM I/O circuit 58 includes adjustable driver output impedances. Also, RAM I/O circuit 58 is similar to I/O circuit 24 (shown in FIG. 1). In one embodiment, RAM I/O circuit 58 includes adjustable driver output impedances that are adjusted via digital steps, where digital circuitry enables and disables parallel drivers to achieve a specified impedance value.

Sensor circuit 80 senses one or more suitable parameters. Sensor circuit 80 is similar to sensor circuit 20. In one embodiment, sensor circuit 80 senses the temperature of RAM 44. In one embodiment, sensor circuit 80 senses the power supply voltage of RAM 44. In one embodiment, sensor circuit 80 senses the temperature and the power supply voltage of RAM 44.

Calibration circuit 82 adjusts the adjustable driver output impedances of RAM I/O circuit 58 to the specified impedance value based on receiving an active calibrate signal. Calibration circuit 82 is similar to calibration circuit 22. If changes in the one or more parameters exceed corresponding change threshold values, an active calibrate signal is provided to calibration circuit 22 and calibration circuit 22 calibrates or adjusts the adjustable driver output impedances. In one embodiment, control circuit 60 provides an active calibrate signal to calibration circuit 82 at power up initialization and calibration circuit 82 adjusts the adjustable driver output impedances of RAM I/O circuit 58 to the specified impedance value for the prevailing process, voltage, and temperature of RAM 44.

Embodiments of RAM 44 are similar to embodiments of second semiconductor device 14. In one embodiment, changes in temperature are compared to a temperature change threshold value and if a change in temperature exceeds the temperature change threshold value an active calibrate signal is provided to the calibration circuit 82. In one embodiment, a change in power supply voltage is compared to a power supply voltage change threshold value and if the change in the power supply voltage exceeds the power supply voltage change threshold value an active calibrate signal is provided to the calibration circuit 82. In one embodiment, a change in temperature is compared to a temperature change threshold value and a change in power supply voltage is compared to a power supply voltage change threshold value and if the change in temperature exceeds the temperature change threshold value and the change in the power supply voltage exceeds the power supply voltage change threshold value an active calibrate signal is provided to the calibration circuit 82. In one embodiment, calibration circuit 82 is powered off after calibrating or adjusting the adjustable output impedances, which reduces power consumption.

In one embodiment, sensor circuit 80 senses one or more parameters and provides sensed signals from the one or more parameters to control circuit 60 via signal path 84. Control circuit 60 compares the sensed signals to the corresponding threshold values and if changes in the one or more parameters exceed the corresponding threshold values, control circuit 60 provides an active calibrate signal to calibration circuit 82 via calibrate signal path 86. Calibration circuit 82 adjusts the adjustable driver output impedances to a specified impedance value based on receiving the active calibrate signal.

In one embodiment, sensor circuit 80 senses one or more parameters and provides sensed signals from the one or more parameters to control circuit 60 via signal path 84. Control circuit 60 receives the sensed signals and provides corresponding sensed signals to controller 42 via communications path 46. Controller 42 compares the sensed signals to the corresponding threshold values and if changes in the one or more parameters exceed the corresponding threshold values, controller 42 provides an active calibrate signal to control circuit 60, which provides the active calibrate signal to calibration circuit 82 via calibrate signal path 86. Calibration circuit 82 adjusts the adjustable driver output impedances to a specified impedance value based on receiving the active calibrate signal.

In one embodiment, sensor circuit 80 senses one or more parameters and compares the sensed signals to the corresponding threshold values. If changes in the one or more parameters exceed the corresponding threshold values, sensor circuit 80 provides an active calibrate signal to control circuit 60 via signal path 84. Control circuit 60 provides a corresponding active calibrate signal to calibration circuit 82 via calibrate signal path 86. Calibration circuit 82 adjusts the adjustable driver output impedances to the specified impedance value based on receiving the active calibrate signal.

In one embodiment, sensor circuit 80 senses the one or more parameters and compares the sensed signals to the corresponding threshold values. If changes in the one or more parameters exceed the corresponding threshold values, sensor circuit 80 provides an active calibrate signal directly to calibration circuit 82 via sensor circuit calibrate signal path 90. Calibration circuit 82 adjusts the adjustable driver output impedances to the specified impedance value based on receiving the active calibrate signal.

In other embodiments, host controller 42 includes a sensor circuit that senses one or more parameters such as temperature and power supply voltage. If changes in the one or more parameters exceed corresponding threshold values, controller 42 provides an active calibrate signal to control circuit 60, which provides the active calibration signal to calibration circuit 82 via calibrate signal path 86. Calibration circuit 82 adjusts the adjustable driver output impedances to the specified impedance value based on receiving the active calibrate signal. In other embodiments, controller 42 communicates directly with sensor circuit 80 and/or calibration circuit 82.

In any embodiment, the calibration algorithm including sensor circuit 80, calibration circuit 82, I/O circuit 58, and control circuit 60 operates in the background of normal operation. Calibration circuit 82 is switched off after adjusting the adjustable driver output impedances of RAM I/O circuit 58, which reduces power consumption. In response to an active calibrate signal, calibration circuit 82 is switched on to adjust the adjustable driver output impedances. Calibrating the output impedances in response to changes in the one or more parameters exceeding corresponding threshold values, substantially prevents toggling between adjacent impedance values and makes it easier to optimize system timing affected by the regulated driver impedances.

In normal operation, during a read operation, control circuit 60 receives read control signals and address register 62 receives the row address of a selected memory cell or cells 68. The row address is supplied from address register 62 to row address latch and decoder 52 and latched into row address latch and decoder 52 by control circuit 60 and a RAS signal. Row address latch and decoder 52 decodes the row address and activates the selected word line 64. As the selected word line 64 is activated, the value stored in each memory cell 68 coupled to the selected word line 64 is passed to the respective bit line 66. The bit values are sensed by sense amplifiers electrically coupled to bit lines 66.

Next, control circuit 60 and address register 62 receive the column address of the selected memory cell or cells 68. The column address is supplied from address register 62 to column address latch and decoder 54 and latched into column address latch and decoder 54 by control circuit 60 and a CAS signal. The column address latch and decoder 54 decodes the column address to select column select lines 70. Control circuit 60 provides control signals to column address latch and decoder 54 to selectively activate column select lines 70 and connect selected sense amplifiers to RAM I/O circuit 58. RAM I/O circuit 58 receives the sensed output values and outputs the sensed output values. Controller 42 or any other suitable circuit receives the output values via data communications path 48.

During a write operation, control circuit 60 receives write control signals and address register 62 receives the row address of a selected memory cell or cells 68. The row address is supplied from address register 62 to row address latch and decoder 52 and latched into row address latch and decoder 52 by control circuit 60 and a RAS signal. The row address latch and decoder 52 decodes the row address and activates the selected word line 64. As the selected word line 64 is activated, the value stored in each memory cell 68 coupled to the selected word line 64 is passed to the respective bit line 66 and the sense amplifier that is electrically coupled to the respective bit line 66.

Control circuit 60 and address register 62 receive the column address of the selected memory cell or cells 68. Address register 62 supplies the column address to column address latch and decoder 54 and the column address is latched into column address latch and decoder 54 by control circuit 60 and a CAS signal. Column address latch and decoder 54 receives column select line activation signals from control circuit 60 and activates selected column select lines 70 to connect sense amplifiers in sense amplifier circuit 56 to RAM I/O circuit 58.

Data to be stored in the array of memory cells 50 is supplied from controller 42 to RAM I/O circuit 58 via data communications path 48. RAM I/O circuit 58 receives the data and provides, data bits to sense amplifiers in sense amplifier circuit 56 via I/O communications path 74. RAM I/O circuit 58 overdrives the sense amplifiers to write data to the selected memory cell or cells 68 via bit lines 66.

FIG. 3 is a diagram illustrating one embodiment of a memory cell 68 in the array of memory cells 50. Memory cell 68 includes a transistor 92 and a capacitor 94. The gate of transistor 92 is electrically coupled to a word line 64. One side of the drain-source path of transistor 92 is electrically coupled to a bit line 66 and the other side of the drain-source path is electrically coupled to one side of capacitor 94. The other side of capacitor 94 is electrically coupled to a reference 96, such as one-half the supply voltage. Capacitor 94 is charged and discharged to represent a logic 0 or a logic 1.

During a read operation, word line 64 is activated to turn on transistor 92. A sense amplifier senses the value stored on capacitor 94 via bit line 66. During a write operation, word line 64 is activated to turn on transistor 92 to access capacitor 94. The sense amplifier connected to bit line 66 is overdriven to write a data value onto capacitor 94 via bit line 66 and transistor 92.

A read operation on memory cell 68 is a destructive read operation. After each read operation, capacitor 94 is recharged or discharged to the data value that was just read. In addition, even without a read operation, the charge on capacitor 94 discharges over time. To retain a stored value, memory cell 68 is refreshed periodically by reading and/or writing memory cell 68. All memory cells 68 in the array of memory cells 50 are periodically refreshed to maintain their values.

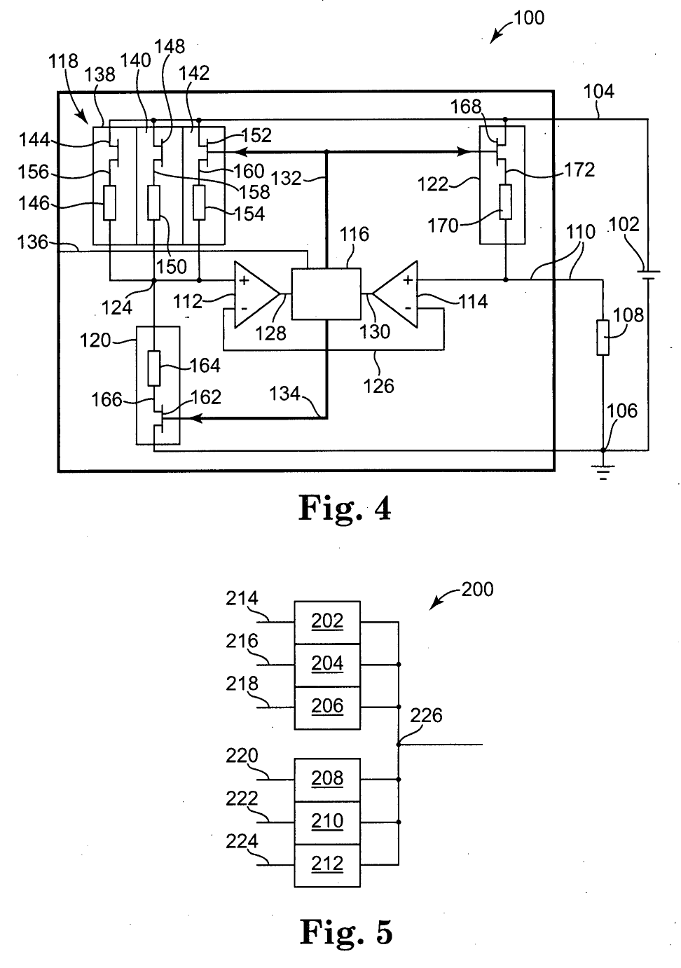

FIG. 4 is a diagram illustrating one embodiment of a calibration circuit 100. One side of power source 102 is electrically coupled to calibration circuit 100 via power supply line 104. The other side of power source 102 is electrically coupled to a reference 106, such as ground. Also, one side of reference resistor 108 is electrically coupled to calibration circuit 100 via reference input path 110. The other side of reference resistor 108 is electrically coupled to reference 106. Calibration circuit 100 is similar to calibration circuit 22 (shown in FIG. 1) and calibration circuit 82 (shown in FIG. 2).

Calibration circuit 100 includes a first comparator 112, a second comparator 114, calibration control logic 116, resistor network 118, first resistive element 120, and second resistive element 122. One input of first comparator 112 is electrically coupled to resistor network 118 and first resistive element 120 via positive input path 124. One input of second comparator 114 is electrically coupled to second resistive element 122 and to reference resistor 108 via reference input path 110. The other input of first comparator 112 is electrically coupled to the other input of second comparator 114 via negative input path 126. The output of first comparator 112 is electrically coupled to calibration control logic 116 via first comparator output path 128. The output of second comparator 114 is electrically coupled to calibration control logic 116 via second comparator output path 130.

Calibration control logic 116 is electrically coupled to resistor network 118 and second resistive element 122 via control bus 132. Calibration control logic 116 is electrically coupled to first resistive element 120 via first element control bus 134. Calibration control logic 116 receives a calibrate signal via calibrate signal input path 136.

Resistor network 118 includes three network elements, first network element 138, second network element 140, and third network element 142. First network element 138 includes a first transistor 144 and a first resistor 146. Second network element 140 includes a second transistor 148 and a second resistor 150. Third network element 142 includes a third transistor 152 and a third resistor 154. In other embodiments, resistor network 118 includes any suitable number of network elements.

One side of the drain-source path of first transistor 144 is electrically coupled to power source 102 via power supply line 104. The other side of the drain-source path of first transistor 144 is electrically coupled at 156 to one side of first resistor 146. The other side of first resistor 146 is electrically coupled to the one input of first comparator 112 via positive input path 124. One side of the drain-source path of second transistor 148 is electrically coupled to power source. 102 via power supply line 104. The other side of the drain-source path of second transistor 148 is electrically coupled at 158 to one side of second resistor 150. The other side of second resistor 150 is electrically coupled to the one input of first comparator 110 via positive input path 124. One side of the drain-source path of third transistor 152 is electrically coupled to power source 102 via power supply line 104. The other side of the drain-source path of third transistor 152 is electrically coupled at 160 to one side of third resistor 154. The other side of third resistor 154 is electrically coupled to the one input of first comparator 110 via positive input path 124. The gates of first transistor 144, second transistor 148, and third transistor 152 are electrically coupled to calibration control logic 116 via control bus 132.

First resistive element 120 includes a fourth transistor 162 and a fourth resistor 164. One side of the drain-source path of fourth transistor 162 is electrically coupled to reference 106. The other side of the drain-source path of fourth transistor 162 is electrically coupled at 166 to one side of fourth resistor 164. The other side of fourth resistor 164 is electrically coupled to the one input of first comparator 112 via positive input path 124. The gate of fourth transistor 162 is electrically coupled to calibration control logic 116 via first element control bus 134. In other embodiments, first resistive element 120 includes any suitable number of transistors and resistors in parallel with fourth transistor 162 and fourth resistor 164.

Second resistive element 122 includes a fifth transistor 168 and a fifth resistor 170. One side of the drain-source path of fifth transistor 168 is electrically coupled to power source 102 via power supply line 104. The other side of the drain-source path of fifth transistor 168 is electrically coupled at 172 to one side of fifth resistor 170. The other side of fifth resistor 170 is electrically coupled to the one input of second comparator 114 via reference input path 110. The gate of fifth transistor 168 is electrically coupled to calibration control logic 116 via control bus 132. In other embodiments, second resistive element 122 includes any suitable number of transistors and resistors in parallel with fifth transistor 168 and fifth resistor 170.

In operation, calibration control logic 116 receives an active calibrate signal at 136. In response to the active calibrate signal at 136, calibration control logic 116 switches on first comparator 112, second comparator 114, circuitry in calibration control logic 116, resistor network 118, first resistive element 120, and second resistive element 122. In one embodiment, the active calibrate signal is provided via a control circuit, such as control circuit 18 or control circuit 60. In one embodiment, the active calibrate signal is provided via a sensor circuit, such as sensor circuit 20 or sensor circuit 80. In one embodiment, the active calibrate signal is provided via another circuit, such as first semiconductor device 12 or controller 42.

First comparator 112 compares the voltage value at 124 to the voltage value at 126 and provides a first comparator output signal at 128 to calibration control logic 116 via first comparator output path 128. Second comparator 114 compares the voltage value at 110 to the voltage value at 126 and provides a second comparator output signal at 130 to calibration control logic 116 via second comparator output path 130.

Calibration control logic 116 compares the output signals at 128 and 130 and provides first control logic output signals at 132 to resistor network 118 and second resistive element 122 via control bus 132 and second control logic output signals at 134 to first resistive element 120 via first element control bus 134. In one embodiment, the first control logic output signals at 132 and/or second control logic output signals at 134 are digital signals. In one embodiment, the first control logic output signals at 132 and/or second control logic output signals at 134 are analog and digital signals. In one embodiment, the first control logic output signals at 132 and/or second control logic output signals at 134 are analog signals.

Calibration control logic 116 adjusts the resistance values of resistor network 118, first resistive element 120, and second resistive element 122. These resistance values are adjusted to correlate the voltage values at 124 and 110. Digital signals from calibration control logic 116 that correspond to the adjustment made to correlate voltage values at 124 and 110 are provided to an I/O circuit, such as I/O circuit 24 or RAM I/O circuit 58 to adjust the adjustable driver output impedances. The adjustable driver output impedances are adjusted to an impedance value that corresponds to the value of reference resistor 108. In one embodiment, calibration control logic 116 adjusts the resistance values of resistor network 118, first resistive element 120, and second resistive element 122 to equalize the voltage values at 124 and 110.

Calibration control logic 100 switches off first comparator 112, second comparator 114, circuitry in calibration control logic 116, resistor network 118, first resistive element 120, and second resistive element 122 after the digital values are provided to an I/O circuit. Switching off circuitry in calibration circuit 100 reduces power consumption. The process is repeated if calibration control logic 116 receives another active calibrate signal at 136. In one embodiment, an active calibrate signal is provided to calibration control logic 100 at power up initialization.

FIG. 5 is a diagram illustrating one embodiment of an I/O circuit 200. I/O circuit 200 includes three pull up drivers, first driver 202, second driver 204, and third driver 206 and three pull down drivers, fourth driver 208, fifth driver 210, and sixth driver 212. I/O circuit 200 is similar to I/O circuit 24 and RAM I/O circuit 58. In other embodiments, I/O circuit 200 can include any suitable number of pull up drivers and pull down drivers.

First driver 202 receives a first input signal at 214. Second driver 204 receives a second input signal at 216. Third driver 206 receives a third input signal at 218. Fourth driver 208 receives a fourth input signal at 220. Fifth driver 210 receives a fifth input signal at 222. Sixth driver 212 receives a sixth input signal at 224. The outputs of first driver 202, second driver 204, third driver 206, fourth driver 208, fifth driver 210, and sixth driver 212 are electrically coupled together via driver output path 226. In one embodiment, the input signals at 214, 216, 218, 220, 222, and 224 are digital input signals.

Each of the drivers 202, 204, 206, 208, 210, and 212 is biased on or off via the corresponding one of the input signals 214, 216, 218, 220, 222, and 224. Also, each of the drivers 202, 204, 206, 208, 210, and 212 provides an output impedance value. Calibration control logic 116 adjusts the driver output impedance of I/O circuit 200 via biasing selected drivers 202, 204, 206, 208, 210, and 212 on or off to provide a specified output impedance value.

Calibration control logic 116 adjusts the resistance values of resistor network 118, first resistive element 120, and second resistive element 122 to correlate the voltage values at 124 and 110. Digital signals that correspond to the adjustment made to correlate voltage values at 124 and 110 are provided to I/O circuit 200 from calibration control logic 116. These digital signals bias drivers 202, 204, 206, 208, 210, and 212 on or off to provide the specified output impedance value. The driver output impedance is adjusted to an impedance value that corresponds to the value of reference resistor 108.

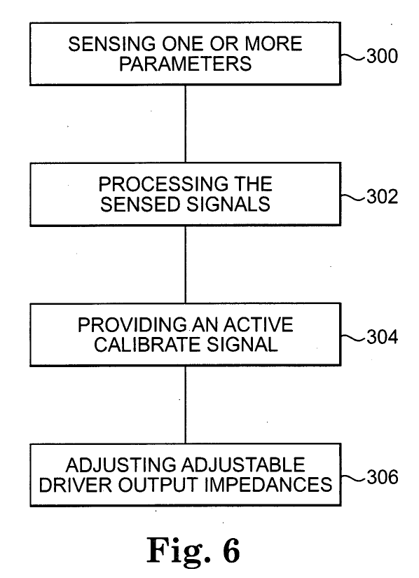

FIG. 6 is a flow chart diagram illustrating one embodiment of regulating adjustable driver output impedances. At 300, a sensor circuit, such as sensor circuit 20 or sensor circuit 80, senses one or more parameters. In one embodiment, the sensor circuit senses the temperature. In one embodiment, the sensor circuit senses the power supply voltage. In other embodiments, the sensor circuit senses the temperature and the power supply voltage.

At 302, the sensed signals are processed. If changes in the one or more parameters exceed corresponding threshold values, an active calibrate signal is provided at 304 to a calibration circuit, such as calibration circuit 22 or calibration circuit 82.

In one embodiment, the sensor circuit senses one or more parameters and provides the sensed signals to a control circuit, such as control circuit 18 or control circuit 60. The control circuit processes the sensed signals and if changes in the one or more parameters exceed corresponding threshold values, the control circuit provides the active calibrate signal.

In one embodiment, the sensor circuit senses one or more parameters and provides the sensed signals from the one or more parameters to a control circuit, such as control circuit 18 or control circuit 60. The control circuit receives the sensed signals and provides corresponding sensed signals to another circuit, such as first semiconductor device 12 or controller 42. The other circuit processes the sensed signals and if changes in the one or more parameters exceed corresponding threshold values, provides an active calibrate signal to the control circuit, which provides the active calibration signal to the calibration circuit. In other embodiments, the other circuit communicates directly with the sensor circuit and/or the calibration circuit.

In one embodiment, the sensor circuit senses the one or more parameters and processes the sensed signals from the one or more parameters. If changes in the one or more parameters exceed corresponding threshold values, the sensor circuit provides the active calibrate signal to a control circuit, such as control circuit 18 or control circuit 60. The control circuit provides a corresponding active calibrate signal to the calibration circuit.

In one embodiment, the sensor circuit senses the one or more parameters and processes the sensed signals from the one or more parameters. If changes in the one or more parameters exceed corresponding threshold values, the sensor circuit provides the active calibrate signal directly to the calibration circuit.

At 306, a calibration circuit, such as calibration circuit 22 or calibration circuit 82, adjusts the adjustable driver output impedances to the specified impedance value based on receiving the active calibrate signal. In one embodiment, an active calibrate signal is provided to the calibration circuit at power up initialization also. In one embodiment, the calibration circuit is powered off after calibrating or adjusting the adjustable output impedances, which reduces power consumption.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a first circuit configured to drive output signals and including an adjustable output impedance;
a second circuit configured to adjust the adjustable output impedance; and
a third circuit configured to sense a first parameter and to activate the second circuit to adjust the adjustable output impedance based on changes in the first parameter exceeding a first threshold value.

2. The semiconductor device of claim 1, wherein the third circuit is configured to sense a second parameter and to activate the second circuit to adjust the adjustable output impedance based on changes in the second parameter exceeding a second threshold value.

3. The semiconductor device of claim 2, wherein the third circuit is configured to activate the second circuit to adjust the adjustable output impedance based on a combination of changes in the first parameter and the second parameter.

4. The semiconductor device of claim 1, wherein the third circuit comprises:
a fourth circuit configured to sense at least one of temperature and voltage.

5. The semiconductor device of claim 1, wherein the first threshold value is programmable.

6. The semiconductor device of claim 1, wherein the third circuit comprises:
a fourth circuit configured to sense the first parameter and provide an active fourth circuit signal based on changes in the first parameter exceeding the first threshold value, wherein the second circuit adjusts the adjustable output impedance based on the active fourth circuit signal.

7. The semiconductor device of claim 1, wherein the third circuit comprises:
a fourth circuit configured to sense the first parameter and provide sensed signals based on the first parameter; and
a fifth circuit configured to receive the sensed signals and provide an active fifth circuit signal based on changes in the first parameter exceeding the first threshold value, wherein the second circuit adjusts the adjustable output impedance based on the active fifth circuit signal.

8. The semiconductor device of claim 1, wherein the third circuit comprises:
a fourth circuit configured to sense the first parameter and provide sensed signals based on the first parameter; and
a fifth circuit configured to receive the sensed signals and provide corresponding fifth circuit signals to an external circuit, wherein the fifth circuit receives an active external signal from the external circuit based on changes in the first parameter exceeding the first threshold value and the second circuit adjusts the adjustable output impedance based on the active external signal.

9. An electronic system comprising:
a semiconductor device comprising:
an output driver including an adjustable output impedance;
a sensor circuit configured to sense at least one parameter; and
a calibration circuit configured to adjust the adjustable output impedance based on an active calibrate signal that is based on changes in the at least one parameter exceeding at least one threshold value.

10. The electronic system of claim 9, wherein the sensor circuit provides the active calibrate signal.

11. The electronic system of claim 9, wherein the semiconductor device comprises:
a control circuit configured to receive sensor signals from the sensor circuit and provide the active calibrate signal.

12. The electronic system of claim 9, comprising:
a host controller configured to provide the active calibrate signal.

13. The electronic system of claim 12, wherein the semiconductor device comprises:
a control circuit configured to receive sensor signals from the sensor circuit and provide the sensor signals to the host controller.

14. The electronic system of claim 9, wherein the semiconductor device is a random access memory.

15. An electronic system comprising:
means for driving output signals that includes an adjustable output impedance;
means for adjusting the adjustable output impedance;
means for sensing a first parameter; and
means for activating the means for adjusting based on changes in the first parameter exceeding a first threshold value.

16. The electronic system of claim 15, comprising:
means for sensing a second parameter, wherein the means for activating includes means for activating the means for adjusting based on changes in the second parameter exceeding a second threshold value.

17. The electronic system of claim 16, wherein the means for activating comprises:
means for activating the means for adjusting based on a combination of changes in the first parameter and the second parameter.

18. The electronic system of claim 15, wherein the means for sensing provides an active calibrate signal based on changes in the first parameter exceeding the first threshold value and the means for adjusting adjusts the adjustable output impedance based on the active calibrate signal.

19. The electronic system of claim 15, wherein the means for sensing provides sensed signals based on the first parameter and the means for activating comprises:
means for receiving the sensed signals and providing an active calibrate signal based on changes in the first parameter exceeding the first threshold value, wherein the means for adjusting adjusts the adjustable output impedance based on the active calibrate signal.

20. The electronic system of claim 15, wherein the means for sensing provides sensed signals based on the first parameter and the means for activating comprises:
means for receiving the sensed signals and providing corresponding signals to an external circuit, wherein the means for receiving receives an active calibrate signal from the external circuit based on changes in the first parameter exceeding the first threshold value and the means for adjusting adjusts the adjustable output impedance based on the active calibrate signal.

21. A method of regulating output impedance comprising:
driving output signals via an adjustable output impedance;
sensing a first parameter; and
adjusting the adjustable output impedance based on changes in the first parameter exceeding a first threshold value.

22. The method of claim 21, comprising:
sensing a second parameter; and
adjusting the adjustable output impedance based on changes in the second parameter exceeding a second threshold value.

23. The method of claim 21, comprising:
providing an active calibrate signal via a sensing circuit based on changes in the first parameter exceeding the first threshold value; and
wherein adjusting the adjustable output impedance comprises adjusting the adjustable output impedance based on the active calibrate signal.

24. The method of claim 21, comprising:
providing sensed signals based on the first parameter;
receiving the sensed signals at a control circuit;
providing an active calibrate signal via the control circuit based on changes in the first parameter exceeding the first threshold value; and
wherein adjusting the adjustable output impedance comprises adjusting the adjustable output impedance based on the active calibrate signal.

25. The method of claim 21, comprising:
providing sensed signals based on the first parameter;
receiving the sensed signals at a control circuit;
providing control circuit signals corresponding to the sensed signals to an external circuit via the control circuit;
providing an active calibrate signal via the external circuit based on changes in the first parameter exceeding the first threshold value; and
wherein adjusting the adjustable output impedance comprises adjusting the adjustable output impedance based on the active calibrate signal.

26. A method of regulating output impedance comprising:
driving outputs via an adjustable output impedance;
sensing at least one parameter of temperature and voltage; and
calibrating the adjustable output impedance based on an active calibrate signal that is based on changes in the sensed at least one parameter exceeding at least one threshold value.

27. The method of claim 26, comprising:
providing the active calibrate signal via a sensor circuit.

28. The method of claim 26, comprising:
receiving sensed signals corresponding to the sensed at least one parameter at a control circuit; and
providing the active calibrate signal via the control circuit.
